(19) United States
(12) Patent Application Publication
(10) Pub. No.: US 2026/0334231 A1
(43) Pub. Date: Oct. 22, 2026

(54) HEAT DISSIPATION STRUCTURES FOR INTEGRATED CIRCUIT PACKAGES AND METHODS OF FORMING THE SAME

(71) Applicant: Taiwan Semiconductor Manufacturing Co., Ltd., Hsinchu (TW)

(72) Inventors: Szu-Wei Lu, Hsinchu (TW); Tsung-Fu Tsai, Changhua City (TW); Chi-Hsiang Chen, Taipei City (TW)

(21) Appl. No.: 19/723,526

(22) Filed: Jun. 29, 2026

Related U.S. Application Data
(62) Division of application No. 17/837,312, filed on Jun. 10, 2022.

(51) Int. Cl. H10W 40/73; H10W 40/00; H10W 74/01; H10W 90/00; H10W 74/00; H10W 74/15; H10W 76/10

(52) U.S. Cl. CPC H10W 40/73; H10W 40/037; H10W 74/016; H10W 90/00; H10W 74/00; H10W 74/15; H10W 76/10; H10W 90/724; H10W 90/734

(57) ABSTRACT

A device includes a package substrate, an interposer having a first side bonded to the package substrate, a first die bonded to a second side of the interposer, the second side being opposite the first side, a ring on the package substrate, where the ring surrounds the first die and the interposer, a molding compound disposed between the ring and the first die, where the molding compound is in physical contact with the ring, and a plurality of thermal-conductive layers over and in physical contact with the molding compound and the first die, where the molding compound is disposed between the plurality of thermal-conductive layers and the ring.

### CROSS-REFERENCE TO RELATED APPLICATIONS

This application is a divisional of U.S. Patent Application No. 17/837,312 filed on Jun. 10, 2022, which application is hereby incorporated herein by reference.

### BACKGROUND

Since the development of the integrated circuit (IC), the semiconductor industry has experienced continued rapid growth due to continuous improvements in the integration density of various electronic components (i.e., transistors, diodes, resistors, capacitors, etc.). For the most part, these improvements in integration density have come from repeated reductions in minimum feature size, which allows more components to be integrated into a given area.

These integration improvements are essentially two-dimensional (2D) in nature, in that the area occupied by the integrated components is essentially on the surface of the semiconductor wafer. The increased density and corresponding decrease in area of the integrated circuit has generally surpassed the ability to bond an integrated circuit chip directly onto a substrate. Interposers have been used to redistribute ball contact areas from that of the chip to a larger area of the interposer. Further, interposers have allowed for a three-dimensional (3D) package that includes multiple chips. Other packages have also been developed to incorporate 3D aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 16A are cross-sectional views of intermediate stages in the manufacturing of a package structure, in accordance with some embodiments.

FIG. 16B is a cross-sectional view of an intermediate stage in the manufacturing of a package structure, in accordance with some other embodiments.

FIGS. 17A through 17F are cross-sectional views of intermediate stages in the manufacturing of a package structure, in accordance with some other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include methods for forming a device package (e.g., a chip-on-wafer-on-substrate (CoWoS) package) comprising a package component (e.g., a chip-on-wafer package component comprising one or more semiconductor chips bonded to an interposer) and a package substrate bonded to a side of the interposer opposing the one or more semiconductor chips. A ring is attached to the substrate, wherein the ring surrounds the package component, and a molding compound is formed to fill spaces between the ring and the package component. A plurality of thermal-conductive metal layers is then formed over and in physical contact with the package component and the molding compound. A thermal interface material (TIM) is applied to a top surface of the plurality of conductive metal layers and a liquid cooling device (for example, a liquid cooled cold-plate or other suitable device) is thereafter coupled to the plurality of thermal-conductive metal layers, by way of the TIM. Advantageous features of some embodiments disclosed herein include the use of only one application of TIM, which results in reduced thermal resistance and improved cooling performance of the liquid cooling device.

Embodiments will be described with respect to a specific context, namely a Die-Interposer-Substrate stacked package using Chip-on-Wafer-on-Substrate (CoWoS) processing. Other embodiments may also be applied, however, to other packages, such as a Die-Die-Substrate stacked package, a System-on-Integrated-Chip (SoIC) device package, an Integrated Fan-Out (InFO) package, and other processing.

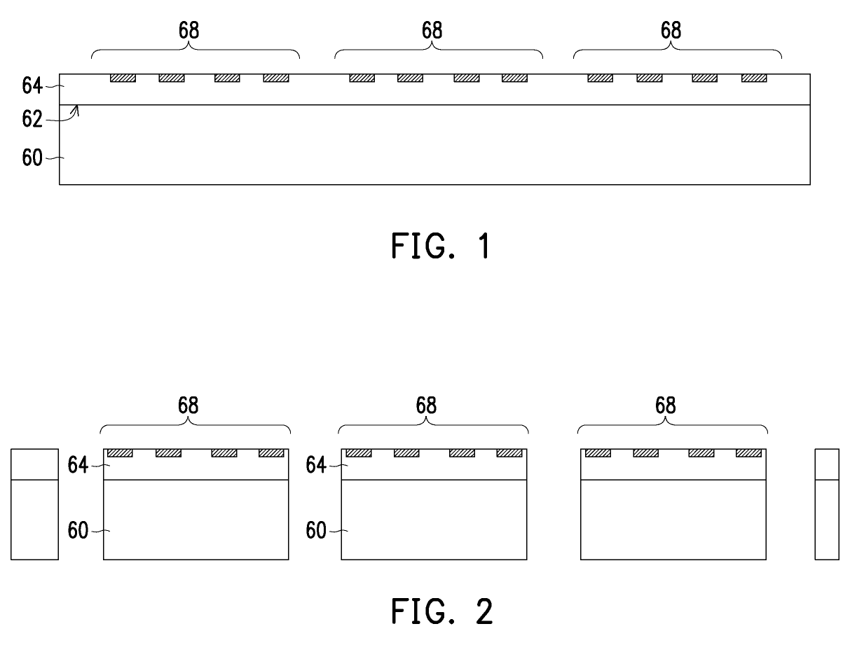

FIGS. 1 through 16 illustrate cross-sectional views of intermediate stages in the manufacturing of a package structure 10 in accordance with some embodiments. FIG. 1 illustrates one or more dies 68. A main body 60 of the dies 68 may comprise any number of dies, substrates, transistors, active devices, passive devices, or the like. In an embodiment, the main body 60 may include a bulk semiconductor substrate, semiconductor-on-insulator (SOI) substrate, multi-layered semiconductor substrate, or the like. The semiconductor material of the main body 60 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The main body 60 may be doped or undoped. Devices, such as transistors, capacitors, resistors, diodes, and the like, may be formed in and/or on an active surface 62 of the main body 60.

An interconnect structure 64 comprising one or more dielectric layer(s) and respective metallization pattern(s) is formed on the active surface 62. The metallization pattern(s) in the dielectric layer(s) may route electrical signals between the devices, such as by using vias and/or traces, and may also contain various electrical devices, such as capacitors, resistors, inductors, or the like. The various devices and metallization patterns may be interconnected to perform one or more functions. The functions may include memory structures, processing structures, sensors, amplifiers, power distribution, input/output circuitry, or the like. Additionally, die connectors, such as conductive pillars (for example, comprising a metal such as copper), are formed in and/or on the interconnect structure 64 to provide an external electrical connection to the circuitry and devices.

As an example to form a layer of the interconnect structure 64, an inter-metallization dielectric (IMD) layer may be formed. The IMD layer may be formed, for example, of a low-K dielectric material, such as phosphosilicate glass (PSG), borophosphosilicate glass (BPSG), fluorosilicate glass (FSG), SiOₓC_{y}, Spin-On-Glass, Spin-On-Polymers, silicon carbon material, compounds thereof, composites thereof, combinations thereof, or the like, by any suitable method known in the art, such as spinning, chemical vapor deposition (CVD), plasma-enhanced CVD (PECVD), high-density plasma chemical vapor deposition (HDP-CVD), or the like. A metallization pattern may be formed in the IMD layer, for example, by using photolithography techniques to deposit and pattern a photoresist material on the IMD layer to expose portions of the IMD layer that are to become the metallization pattern. An etch process, such as an anisotropic dry etch process, may be used to create recesses and/or openings in the IMD layer corresponding to the exposed portions of the IMD layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by atomic layer deposition (ALD), or the like. The conductive material of the metallization patterns may comprise copper, aluminum, tungsten, silver, and combinations thereof, or the like, deposited by CVD, physical vapor deposition (PVD), or the like. Any excessive diffusion barrier layer and/or conductive material on the IMD layer may be removed, such as by using a chemical mechanical polish (CMP). Additional layers of the interconnect structure 64 may be formed by repeating these steps.

In FIG. 2, the main body 60 including the interconnect structure 64 is singulated into individual dies 68. Typically, each of the dies 68 contains the same circuitry, such as the same devices and metallization patterns, although some or all of the dies 68 may have different circuitry. The singulation may include sawing, dicing, or the like.

Each of the dies 68 may include one or more logic dies (e.g., central processing unit, graphics processing unit, system-on-a-chip, field-programmable gate array (FPGA), microcontroller, or the like), memory dies (e.g., dynamic random access memory (DRAM) die, static random access memory (SRAM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. Also, in some embodiments, the dies 68 may be different sizes (e.g., different heights and/or surface areas), and in other embodiments, the dies 68 may be the same size (e.g., same heights and/or surface areas).

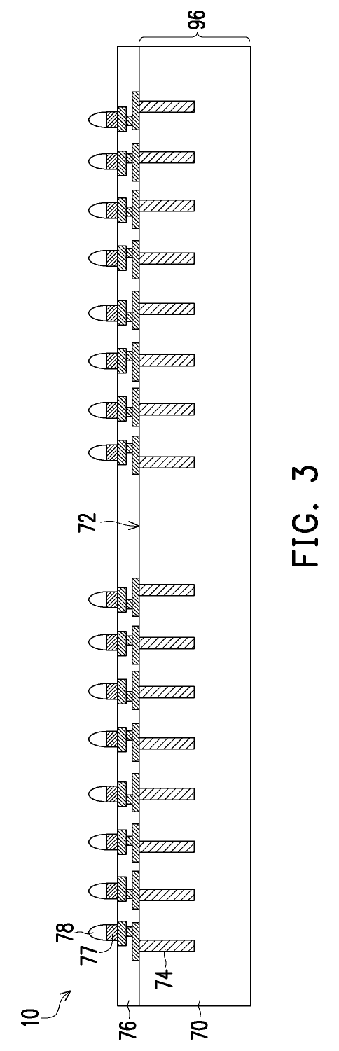

FIG. 3 illustrates one or more components 96 during processing. The components 96 may be interposers or other dies. A substrate 70 may form the main body of the components 96. The substrate 70 can be a wafer. The substrate 70 may comprise a bulk semiconductor substrate, SOI substrate, multi-layered semiconductor substrate, or the like. The semiconductor material of the substrate 70 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 70 may be doped or undoped. Devices, such as transistors, capacitors, resistors, diodes, and the like, may be formed in and/or on a first surface 72, which may also be referred to as an active surface, of the substrate 70. In embodiments where the components 96 are interposers, the components 96 will generally not include active devices therein, although the interposer may include passive devices formed in and/or on a first surface 72. In such embodiments, the components 96 may be free of any active devices on the substrate 70.

Through-vias (TVs) 74 are formed to extend from the first surface 72 of substrate 70 into substrate 70. The TVs 74 are also sometimes referred to as through-substrate vias, or through-silicon vias when substrate 70 is a silicon substrate. The TVs 74 may be formed by forming recesses in the substrate 70 by, for example, etching, milling, laser techniques, a combination thereof, and/or the like. A thin dielectric material may be formed in the recesses, such as by using an oxidation technique. A thin barrier layer may be conformally deposited over the front side of the substrate 70 and in the openings, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 70 by, for example, CMP. Thus, the TVs 74 may comprise a conductive material and a thin barrier layer between the conductive material and the substrate 70.

Interconnect structure 76 is formed over the first surface 72 of the substrate 70, and is used to electrically connect the integrated circuit devices, if any, and/or TVs 74 together and/or to external devices. The interconnect structure 76 may include one or more dielectric layer(s) and respective metallization pattern(s) in the dielectric layer(s). The metallization patterns may comprise vias and/or traces to interconnect any devices and/or TVs 74 together and/or to an external device. The dielectric layers may comprise silicon oxide, silicon nitride, silicon carbide, silicon oxynitride, low-K dielectric material, such as PSG, BPSG, FSG, SiOₓC_{y}, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. A metallization pattern may be formed in the dielectric layer, for example, by using photolithography techniques to deposit and pattern a photoresist material on the dielectric layer to expose portions of the dielectric layer that are to become the metallization pattern. An etch process, such as an anisotropic dry etch process, may be used to create recesses and/or openings in the dielectric layer corresponding to the exposed portions of the dielectric layer. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVC, or the like. Any excessive diffusion barrier layer and/or conductive material on the dielectric layer may be removed, such as by using a CMP.

Electrical connectors 77/78 are formed at the top surface of the interconnect structure 76, such as on conductive pads that are formed in the dielectric layers of the interconnect structure 76. In some embodiments, the electrical connectors 77/78 include metal pillars 77 with metal cap layers 78, which may be solder caps, over the metal pillars 77. The electrical connectors 77/78 (including the pillars 77 and the cap layers 78) are sometimes referred to as micro bumps 77/78. In some embodiments, the metal pillars 77 include a conductive material such as copper, aluminum, gold, nickel, palladium, the like, or a combination thereof and may be formed by sputtering, printing, electro plating, electroless plating, CVD, or the like. The metal pillars 77 may be solder free and have substantially vertical sidewalls. In some embodiments, respective metal cap layers 78 are formed on the respective top surfaces of the metal pillars 77. The metal cap layers 78 may include nickel, tin, tin-lead, gold, copper, silver, palladium, indium, nickel-palladium-gold, nickel-gold, the like, or a combination thereof and may be formed by a plating process.

In another embodiment, the electrical connectors 77/78 do not include the metal pillars and are solder balls and/or bumps, such as controlled collapse chip connection (C4), electroless nickel immersion Gold (ENIG), electroless nickel electroless palladium immersion gold technique (ENEPIG) formed bumps, or the like. In such embodiments, the bump electrical connectors 77/78 may include a conductive material such as solder, copper, aluminum, gold, nickel, silver, palladium, tin, the like, or a combination thereof. The electrical connectors 77/78 may be formed by initially forming a layer of solder through methods such as evaporation, electroplating, printing, solder transfer, ball placement, or the like. Once a layer of solder has been formed on the structure, a reflow may be performed in order to shape the material into the desired bump shapes.

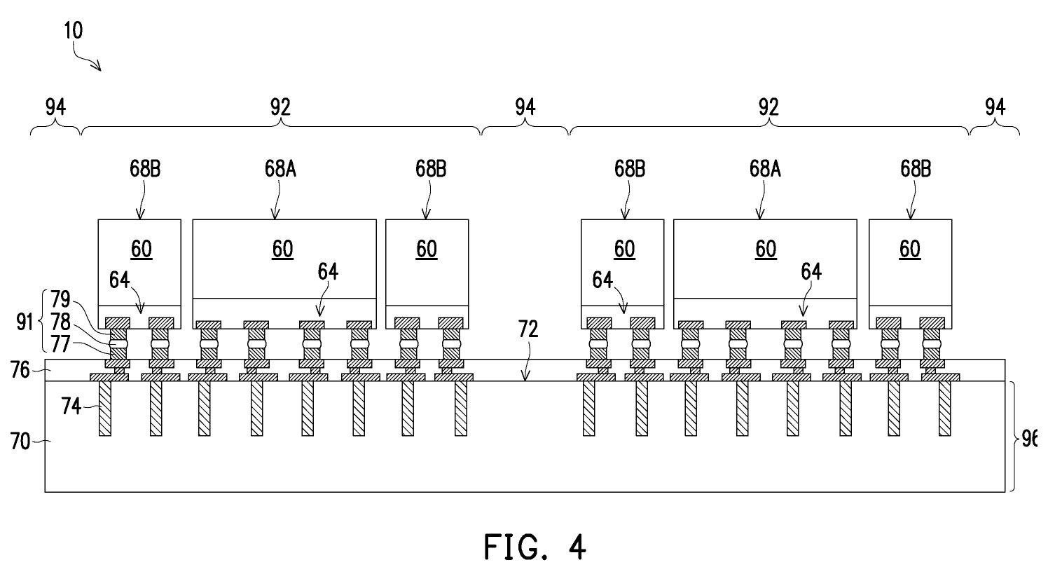

In FIG. 4, dies 68 (including dies 68A and dies 68B) are attached to the first side of the components 96, for example, through flip-chip bonding by way of the electrical connectors 77/78 and metal pillars 79 on the dies to form conductive joints 91. The metal pillars 79 may be similar to the metal pillars 77 and the description is not repeated herein. The dies 68 may be placed on the electrical connectors 77/78 using, for example, a pick-and-place tool. In some embodiments, the metal cap layers 78 are formed on the metal pillars 77 (as shown in FIG. 3), the metal pillars 79 of the dies 68, or both.

The dies 68A and the dies 68B may be different types of dies. In some embodiments, the dies 68A include logic dies (e.g., central processing unit, graphics processing unit, system-on-a-chip, field-programmable gate array (FPGA), microcontroller, or the like), memory dies (e.g., dynamic random access memory (DRAM) die, static random access memory (SRAM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. In some embodiments, the dies 68A are system-on-a-chip (SoC) or a graphics processing unit (GPU) dies, and the dies 68B are memory dies that may utilized by the dies 68A. In some embodiments, the dies 68B include one or more memory dies, such as a stack of memory dies (e.g., DRAM dies, SRAM dies, High-Bandwidth Memory (HBM) dies, Hybrid Memory Cubes (HMC) dies, or the like). In the stack of memory dies embodiments, a die 68B can include both memory dies and a memory controller, such as, for example, a stack of four or eight memory dies with a memory controller. Also, in some embodiments, the dies 68B may be different sizes (e.g., different heights and/or surface areas) from the dies 68A, and in other embodiments, the dies 68B may be the same size (e.g., same heights and/or surface areas) as the dies 68A. In some embodiments, the dies 68B may be similar heights to those of the dies 68A (as shown in FIG. 4) or in some embodiments, the dies 68A and 68B may be of different heights.

The conductive joints 91 electrically couple the circuits in the dies 68, through the interconnect structures 64, to the interconnect structure 76 and the TVs 74 in the components 96. Additionally, the interconnect structure 76 electrically interconnects the dies 68A and the dies 68B to each other.

In some embodiments, before bonding the electrical connectors 77/78, the electrical connectors 77/78 are coated with a flux (not shown), such as a no-clean flux. The electrical connectors 77/78 may be dipped in the flux or the flux may be jetted onto the electrical connectors 77/78. In another embodiment, the flux may also be applied to the electrical connectors 79/78. In some embodiments, the electrical connectors 77/78 and/or 79/78 may have an epoxy flux (not shown) formed thereon before they are reflowed with at least some of the epoxy portion of the epoxy flux remaining after the dies 68 are attached to the components 96. This remaining epoxy portion may act as an underfill to reduce stress and protect the joints resulting from the reflowing the electrical connectors 77/78/79.

The bonding between the dies 68 and the components 96 may be a solder bonding or a direct metal-to-metal (such as a copper-to-copper or tin-to-tin) bonding. In an embodiment, the dies 68 are bonded to the components 96 by a reflow process. During this reflow process, the electrical connectors 77/78/79 are in contact to physically and electrically couple the dies 68 to the components 96. After the bonding process, an IMC (not shown) may form at the interface of the metal pillars 77/79 and the metal cap layers 78.

In FIG. 4 and subsequent figures, a first package region 90 and a second package region 92 for the formation of a first package and a second package, respectively, are illustrated. Scribe line regions 94 are between adjacent package regions. As illustrated in FIG. 4, a single die 68A and multiple dies 68B are attached in each of the first package region 90 and the second package region 92.

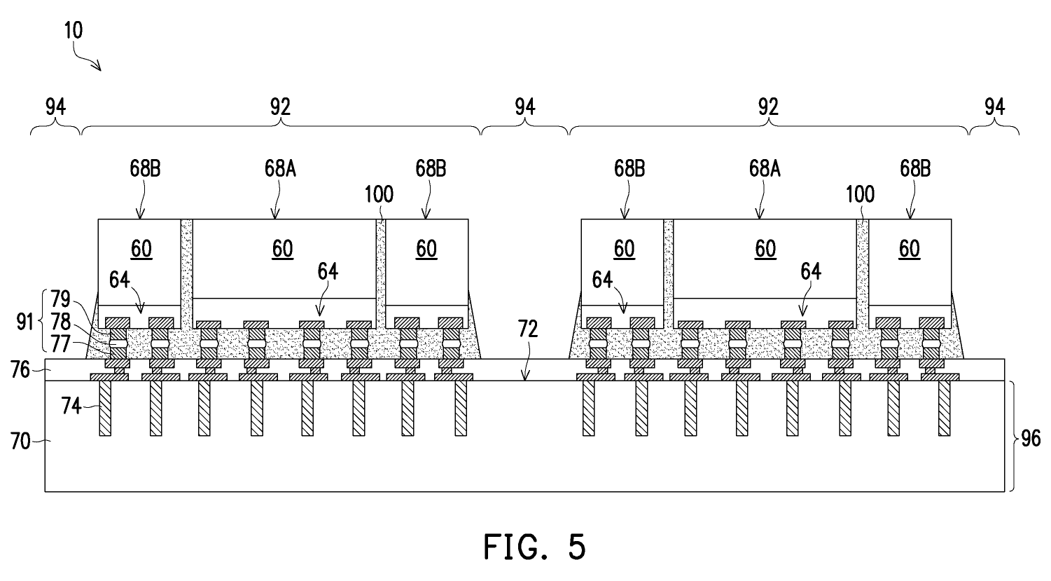

In FIG. 5, an underfill material 100 is dispensed into the gaps between the dies 68 and the interconnect structure 76. The underfill material 100 may extend up along sidewall of the dies 68A and the dies 68B. The underfill material 100 may be any acceptable material, such as a polymer, epoxy, molding underfill, or the like. The underfill material 100 may be formed by a capillary flow process after the dies 68 are attached, or may be formed by a suitable deposition method before the dies 68 are attached.

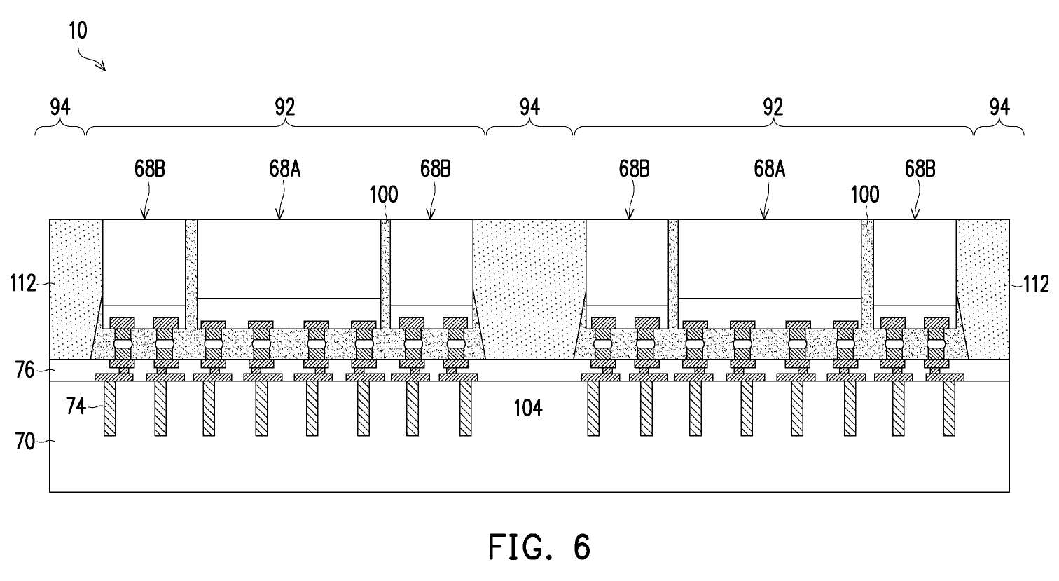

In FIG. 6, an encapsulant 112 is formed on the various components. The encapsulant 112 may be a molding compound, epoxy, or the like, and may be applied by compression molding, transfer molding, or the like. A curing step is performed to cure the encapsulant 112, such as a thermal curing, an Ultra-Violet (UV) curing, or the like. In some embodiments, the dies 68 are buried in the encapsulant 112, and after the curing of the encapsulant 112, a planarization step, such as a grinding, may be performed to remove excess portions of the encapsulant 112, which excess portions are over top surfaces of the dies 68. Accordingly, top surfaces of dies 68 are exposed, and are level with a top surface of the encapsulant 112. In some embodiments, the dies 68B may be different heights from the dies 68A, and the dies 68B will still be covered by the encapsulant 112 after the planarization step.

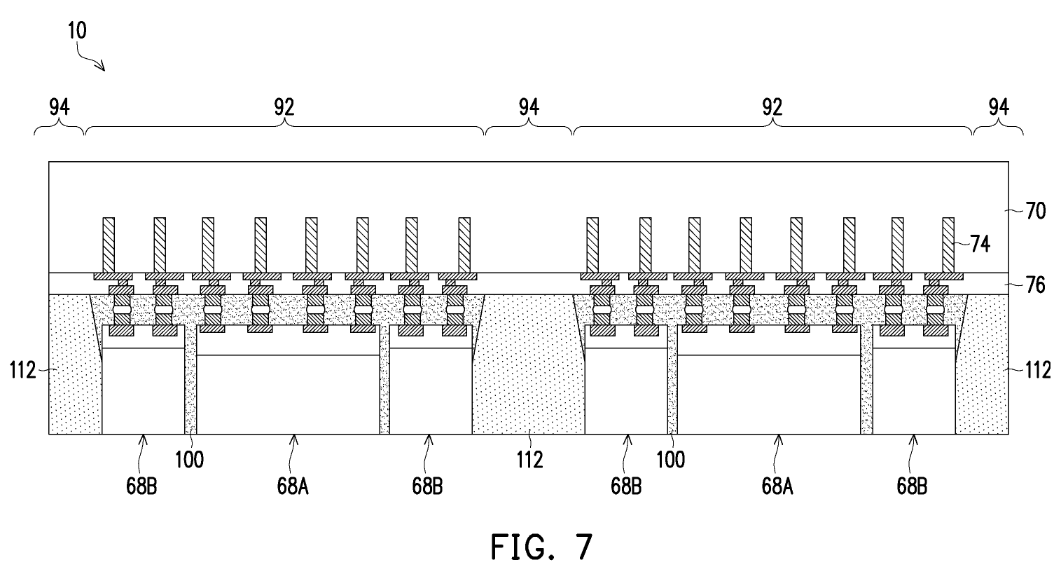

FIGS. 7 through 10 illustrate the formation of the second side of components 96. In FIG. 7, the structure of FIG. 6 is flipped over to prepare for the formation of the second side of components 96. Although not shown, the structure may be placed on carrier or support structure for the process of FIGS. 7 through 10.

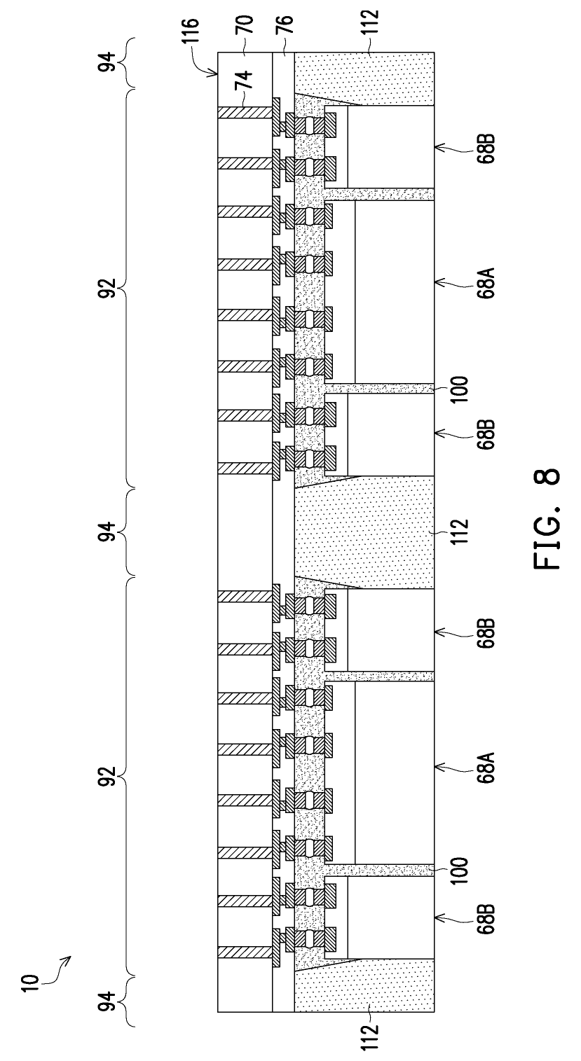

In FIG. 8, a thinning process is performed on the second side of the substrate 70 to thin the substrate 70 until TVs 74 are exposed. The thinning process may include an etching process, a grinding process, the like, or a combination thereof, applied to a second surface 116 of the substrate 70.

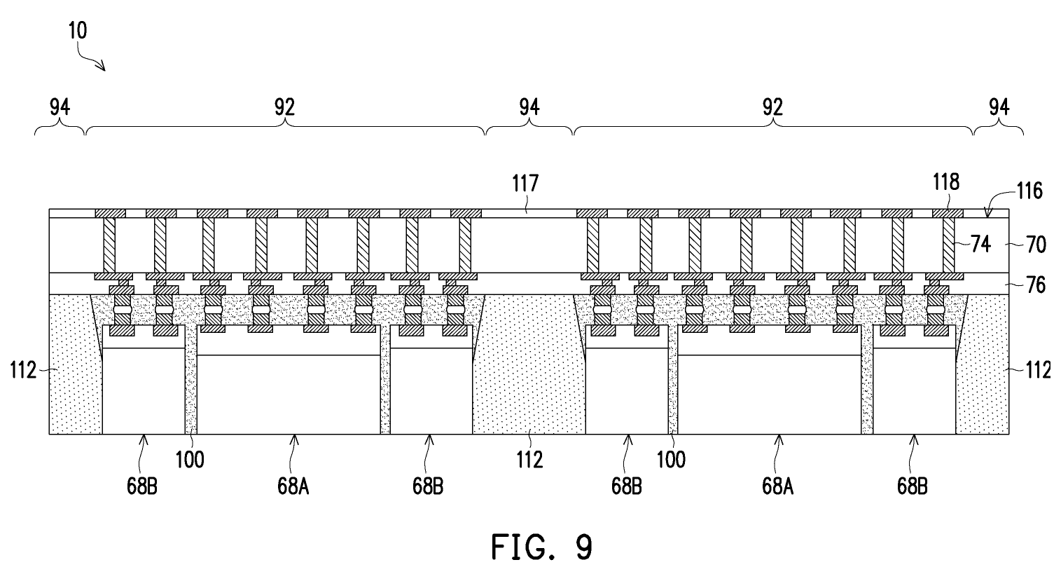

In FIG. 9, a redistribution structure is formed on the second surface 116 of the substrate 70, and is used to electrically connect the TVs 74 together and/or to external devices. The redistribution structure includes a dielectric layer 117 and metallization patterns 118 in and/or on the dielectric layer 117. The metallization patterns may comprise vias and/or traces to interconnect TVs 74 together and/or to an external device. The metallization patterns 118 are sometimes referred to as Redistribution Lines (RDLs). The dielectric layer 117 may comprise silicon oxide, silicon nitride, silicon carbide, silicon oxynitride, low-K dielectric material, such as PSG, BPSG, FSG, SiOₓC_{y}, Spin-On-Glass, Spin-On-Polymers, silicon carbon material, compounds thereof, composites thereof, combinations thereof, or the like. The dielectric layer 117 may be deposited by any suitable method known in the art, such as spinning, CVD, PECVD, HDP-CVD, or the like. The metallization patterns 118 may be formed in the dielectric layer 117, for example, by using photolithography techniques to deposit and pattern a photoresist material on the dielectric layer 117 to expose portions of the dielectric layer 117 that are to become the metallization pattern 118. An etch process, such as an anisotropic dry etch process, may be used to create openings in the dielectric layer 117 corresponding to the exposed portions of the dielectric layer 117. A seed layer (not separately illustrated) is formed over the exposed surfaces of the dielectric layer 117 and in the openings. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization patterns 118. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the metallization patterns 118.

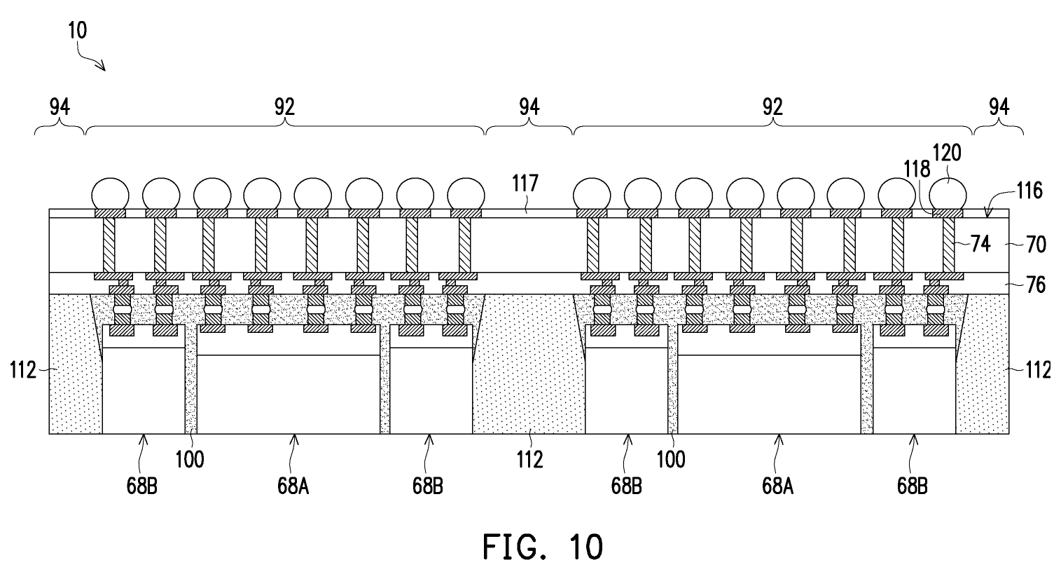

In FIG. 10, electrical connectors 120 are formed the metallization patterns 118 and are electrically coupled to TVs 74. The electrical connectors 120 are formed at the top surface of the redistribution structure on the metallization patterns 118. In some embodiments, the metallization patterns 118 include UBMs. The electrical connectors 120 can be formed on the UBMs.

In some embodiments, the electrical connectors 120 are solder balls and/or bumps, such as ball grid array (BGA) balls, C4 micro bumps, ENIG formed bumps, ENEPIG formed bumps, or the like. The electrical connectors 120 may include a conductive material such as solder, copper, aluminum, gold, nickel, silver, palladium, tin, the like, or a combination thereof. In some embodiments, the electrical connectors 120 are formed by initially forming a layer of solder through methods such as evaporation, electroplating, printing, solder transfer, ball placement, or the like. Once a layer of solder has been formed on the structure, a reflow may be performed in order to shape the material into the desired bump shapes. In another embodiment, the electrical connectors 120 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillar connectors 120. The metal cap layer may include nickel, tin, tin-lead, gold, silver, palladium, indium, nickel-palladium-gold, nickel-gold, the like, or a combination thereof and may be formed by a plating process.

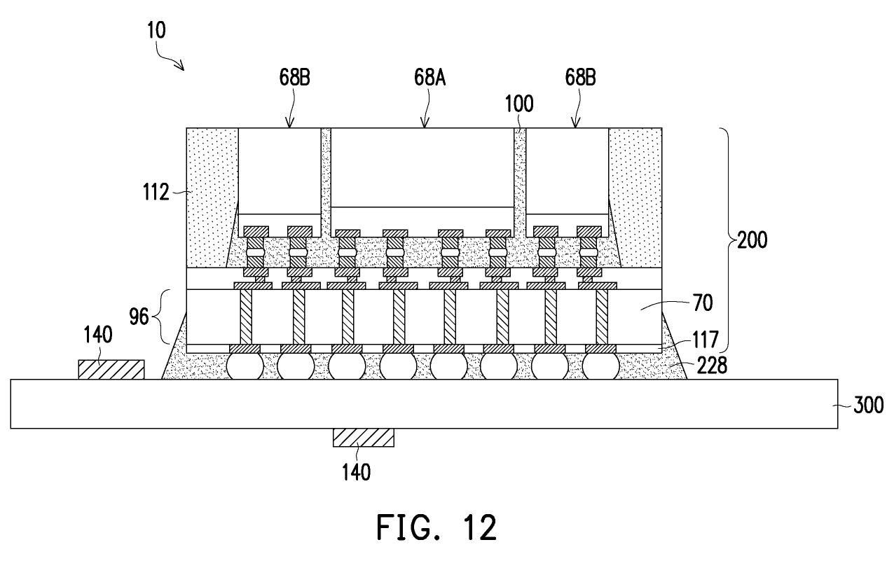

The electrical connectors 120 will be used to bond to an additional electrical component, which may be a semiconductor substrate, a package substrate, a Printed Circuit Board (PCB), or the like (see FIG. 12).

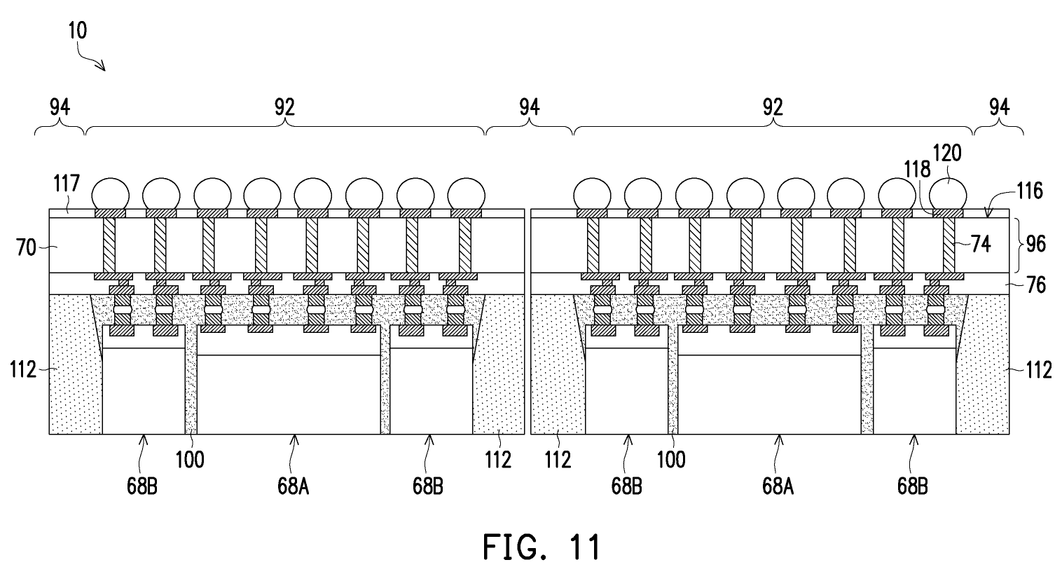

In FIG. 11, components 96 are singulated between adjacent regions 90 and 92 along scribe line regions 94 to form package components 200 comprising, among other things, a die 68A, a component 96, and dies 68B. The singulation may be by sawing, dicing, or the like.

FIG. 12 illustrates the attachment of a package component 200 on a substrate 300. Electrical connectors 120 are aligned to, and are put against, bond pads of the substrate 300. The electrical connectors 120 may be reflowed to create a bond between the substrate 300 and the component 96. The substrate 300 may comprise a package substrate, such as a build-up substrate including a core therein, a laminate substrate including a plurality of laminated dielectric films, a PCB, or the like. The substrate 300 may comprise electrical connectors (not shown), such as solder balls, opposite the package component 200 to allow the substrate 300 to be mounted to another device. An underfill material 228 can be dispensed between the package component 200 and the substrate 300 and surrounding the electrical connectors 120. The underfill material 228 may be any acceptable material, such as a polymer, epoxy, molding underfill, or the like.

Additionally, one or more surface devices 140 may be connected to the substrate 300. The surface devices 140 may be used to provide additional functionality or programming to the package component 200, or the package as a whole. In an embodiment, the surface devices 140 may include surface mount devices (SMDs) or integrated passive devices (IPDs) that include passive devices such as resistors, inductors, capacitors, jumpers, combinations of these, or the like that are desired to be connected to and utilized in conjunction with package component 200, or other parts of the package. The surface devices 140 may be placed on a first major surface of the substrate 300, an opposing major surface of the substrate 300, or both, according to various embodiments.

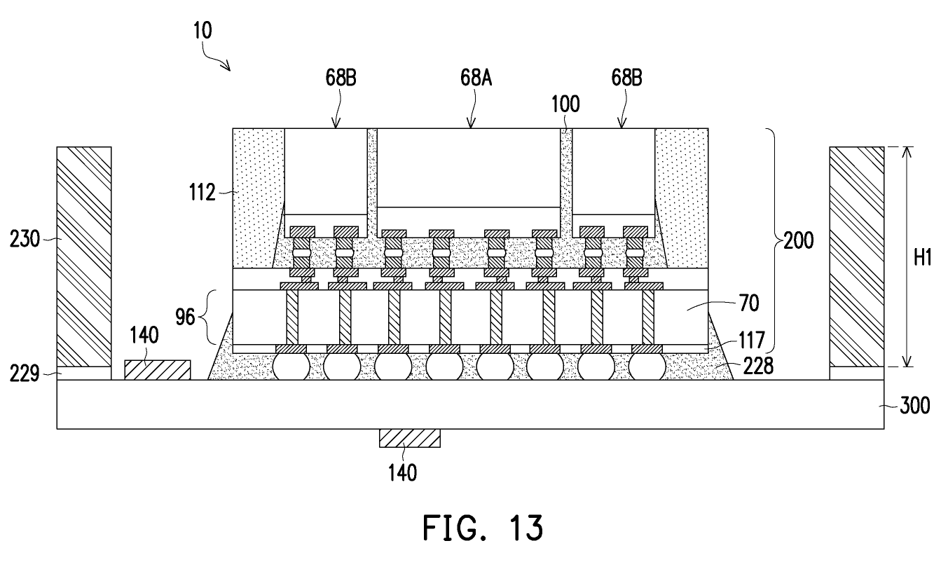

In FIG. 13, an adhesive material 229 is dispensed on the substrate 300. The adhesive material 229 may comprise any material suitable for sealing a component such as a ring 230 or a heat spreader (e.g., a thermal lid or thermal ring) onto the substrate 300, such as epoxies, urethane, polyurethane, silicone elastomers, and the like. The adhesive material 229 may be dispensed to an outer portion or a periphery or edges of the substrate 300.

Further referring to FIG. 13, the ring 230 is placed on the substrate 300 such that the ring 230 surrounds the package component 200. The ring 230 may be formed of a material with high thermal conductivity, such as a metal, such as copper, steel, iron, or the like. The ring 230 protects the package component 200. In an embodiment, a height H1 of the ring 230 may be in a range from 0.5 mm to 2 mm. After the ring is placed on the substrate 300, a suitable curing process may be performed that cures the adhesive material 229 to enable secure attachment of the ring 230 to the substrate 300.

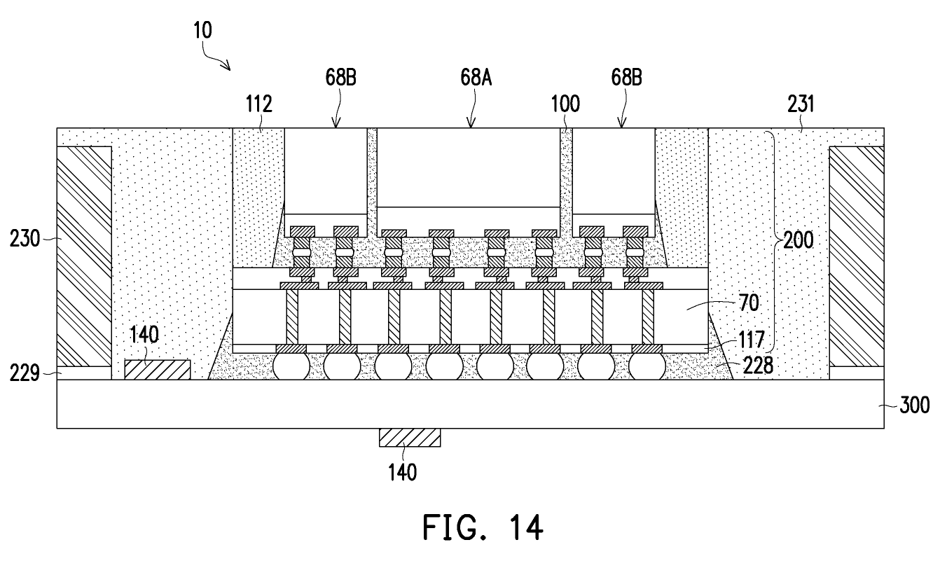

In FIG. 14, a molding compound 231 is formed on the various components. The molding compound 231 may be applied by compression molding, transfer molding, or the like. A curing step may be performed to cure the molding compound 231, such as a thermal curing, an Ultra-Violet (UV) curing, or the like. In some embodiments, the dies 68 are buried in the molding compound 231, with the molding compound disposed between and in physical contact with the ring 230 and the package component 200. In an embodiment, the molding compound 231 is disposed between inner sidewalls of the ring 230 and sidewalls of the package component 200. After the curing of the molding compound 231, a planarization step, such as a grinding, may be performed to remove excess portions of the molding compound 231, which excess portions are over top surfaces of the ring 230, the encapsulant 112, the dies 68. Accordingly, top surfaces of the encapsulant 112 and the dies 68 are exposed, and are level with a top surface of the molding compound 231. Although FIG. 14 illustrates the molding compound 231 as being over a top surface of the ring 230, in other embodiments, a top surface of the molding compound 231 may be level with a top surface of the ring 231. In some embodiments, the molding compound comprises a high thermal conductivity material such as alumina, diamond, aluminum nitride, boron nitride, or the like. For example, the molding compound may comprise these high thermal conductivity small blocks or their combination dispersed in polymer material(s).

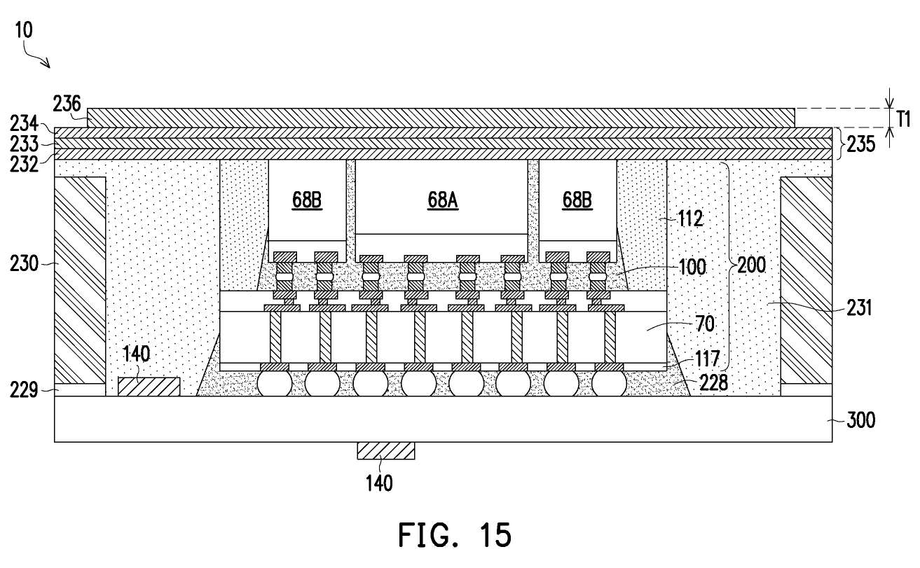

In FIG. 15, a thermal-conductive layer 235 is formed over the top surfaces of the encapsulant 112, the dies 68, and the molding compound 231. The thermal-conductive layer 235 may be a single metal layer or a composite layer comprising a plurality of sub-layers formed of different metals. Each of the plurality of sub-layers may be formed using, for example, deposition processes such as PVD or the like. For example, a first sub-layer of the plurality of sub-layers may be formed over top surfaces of the encapsulant 112, the dies 68, and the molding compound using a first deposition process. A second sub-layer of the plurality of sub-layers may then be formed over the first sub-layer using a second deposition process. A third sub-layer of the plurality of sub-layers may then be formed over the second sub-layer using a third deposition process. Each of the first deposition process, the second deposition process, and the third deposition process may be, for example, different PVD processes. In some embodiments, the thermal-conductive layer 235 may comprise metal sub-layers that are formed from aluminum, titanium, nickel vanadium, gold, copper, or the like. In an embodiment, the thermal-conductive layer 235 may comprise metal sub-layer 232, metal sub-layer 233, and metal sub-layer 234, wherein each of the metal sub-layers 232/233/234 are made of materials that are different from each other. The metal sub-layers 232/233/234 may comprise thermally conductive materials. The metal sub-layer 232 is deposited on the molding compound 231 and the package component 200, the metal sub-layer 233 is deposited on the metal sub-layer 232, and the metal sub-layer 234 is deposited on the metal sub-layer 233. For example, in an embodiment, the metal sub-layer 232 may comprise aluminum, the metal sub-layer 233 may comprise titanium, and the metal sub-layer 234 may comprise nickel vanadium. In an embodiment, the metal sub-layer 232 may comprise aluminum, the metal sub-layer 233 may comprise titanium, and the metal sub-layer 234 may comprise copper. Although FIG. 14 illustrates that the thermal-conductive layer 235 comprises three metal sub-layers, the thermal-conductive layer 235 may comprise fewer or more than three metal sub-layers. For example, in an embodiment where the thermal-conductive layer 235 comprises four metal sub-layers, the thermal-conductive layer 235 may comprise an aluminum layer, a titanium layer over the aluminum layer, a nickel vanadium layer over the titanium layer, and a gold layer over the nickel vanadium layer.

Referring further to FIG. 15, a thermal-conductive layer 236 is then formed on the thermal-conductive layer 235. The thermal-conductive layer 236 may be formed by first forming a photoresist over the thermal-conductive layer 235, and then patterning the photoresist to form an opening through the photo resist that exposes the thermal-conductive layer 235. A conductive material is then formed in the opening of the photo resist and on the exposed portion of the thermal-conductive layer 235 using a technique such as plating (e.g., electroplating or electroless plating), deposition (e.g., PVD), or the like. The thermal-conductive layer 236 may comprise copper, or the like. In an embodiment, the thermal-conductive layer 236 may have a thickness T1 that is in range from 5 µm to 5000 µm. After the thermal-conductive layer 236 is formed, the photoresist may be removed through a suitable removal process such as ashing or chemical stripping.

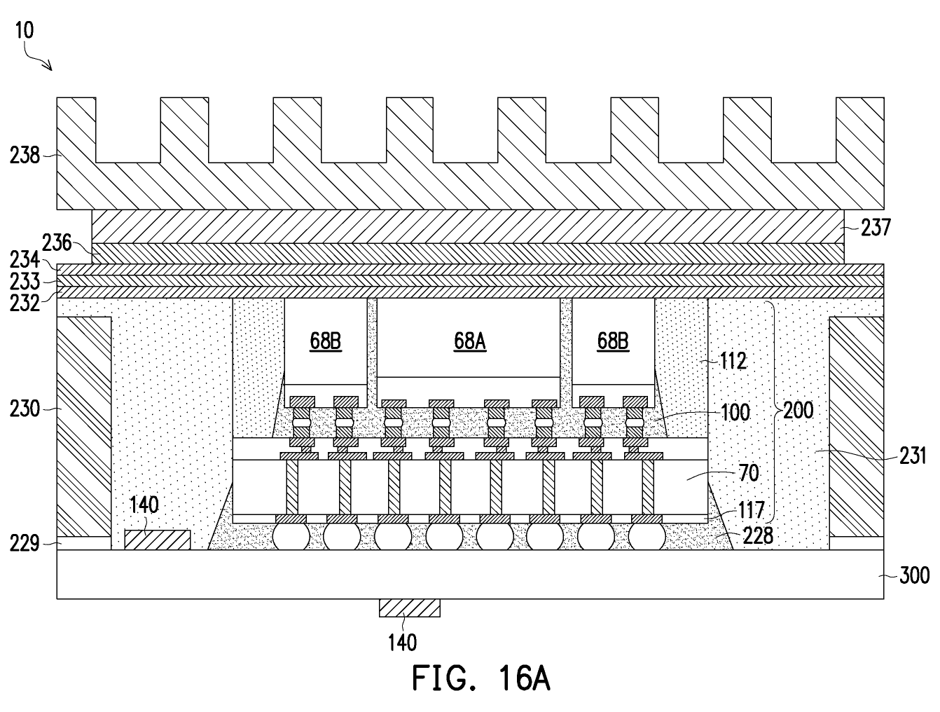

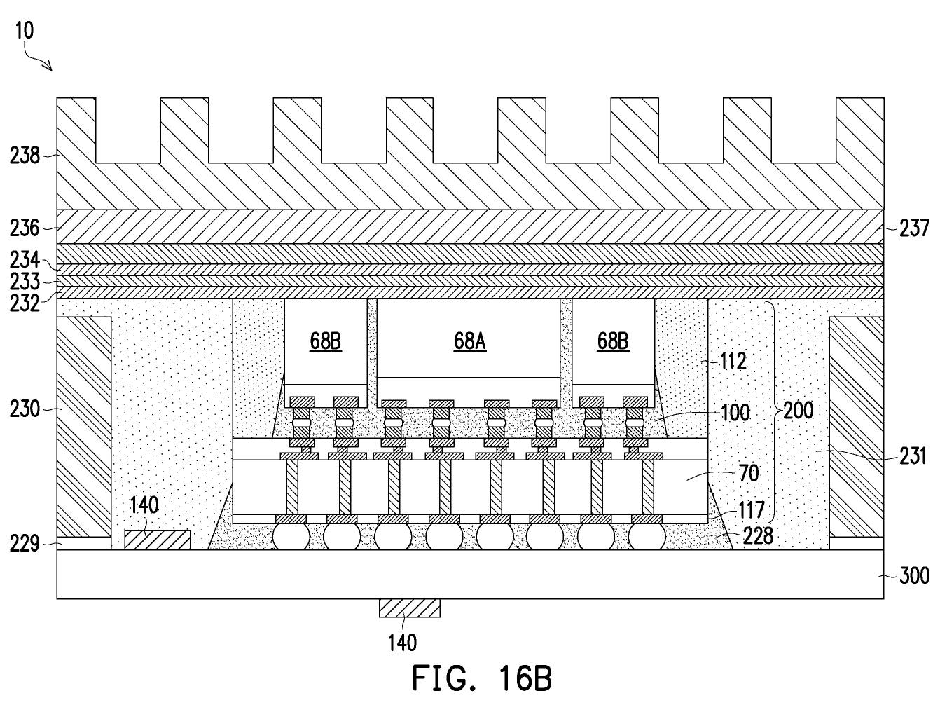

In FIG. 16A, a thermal interface material (TIM) 237 is applied to the top of the thermal-conductive layer 236. The TIM 237 may include but is not limited to, thermal grease, phase change material, metal filled polymer matrix, and solder alloys of lead, tin, indium, silver, copper, bismuth, and the like (most preferred is indium or lead/tin alloy). If the TIM 237 is a solid, it may be heated to a temperature at which it undergoes a solid to liquid transition and then may be applied in liquid form to the top surface of the conductive layer 237.

Further referring to FIG. 16A, a cooling device 238 is placed on the thermal-conductive layer 236, wherein the cooling device 238 is coupled to the thermal-conductive layer 236 by way of the TIM 237. The cooling device may also be referred to subsequently as a heat dissipation structure. In an embodiment, the cooling device 238 may be a liquid cooled cold-plate. In this way, the cooling device 238 can be used to dissipate generated heat by circulating cooling liquid in one or more channels of the cooling device 238. In other embodiments, the cooling device may be any other suitable device that can be used to dissipate heat. For example, in an embodiment, the cooling device 238 may be a heat pipe cooling device, an air (fan) cooling device, or the like. The cooling device 238 comprises a structure that is different from the thermal-conductive layers 235 and 236. Although FIG. 16A illustrates that sidewalls of the TIM 237 and the thermal-conductive layer 236 are offset from sidewalls of the thermal-conductive layer 235, sidewalls of the TIM 237 and the thermal-conductive layer 236 may be aligned with sidewalls of the thermal-conductive layer 235 (e.g., as illustrated in FIG. 16B, which shows the integrated circuit package 10 in accordance with some other embodiments).

Advantages may be achieved as a result of the formation of the package structure 10 comprising the package component 200 bonded to the substrate 300, and thereafter attaching the ring 230 to the substrate 300, wherein the ring surrounds the package component 200. The molding compound 231 is formed to fill spaces between the ring 230 and the package component 200. The thermal-conductive layers 235 and 236 are then formed over and in physical contact with the package component 200. Cooling device 238 is then coupled to the thermal-conductive layers 235 and 236 by way of the TIM 237. These advantages include the use of only one application of the TIM 237, which results in reduced thermal resistance, better heat dissipation, and improved cooling performance of the cooling device 238, and are not limited thereto.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

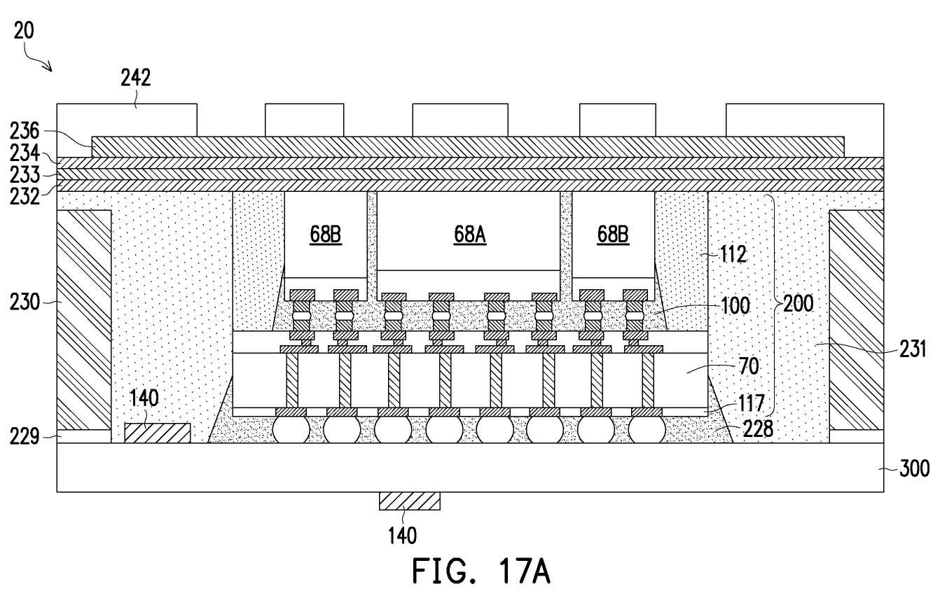

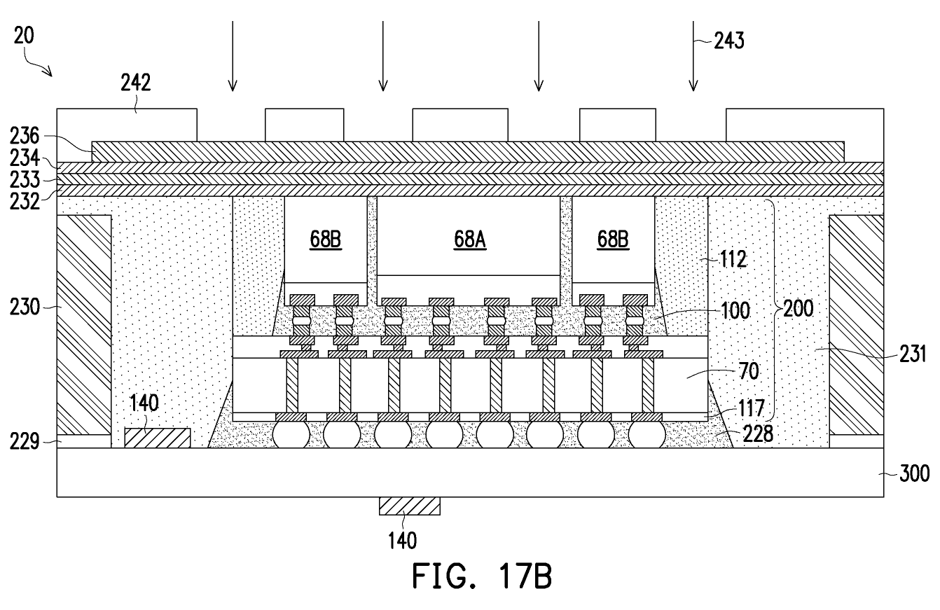

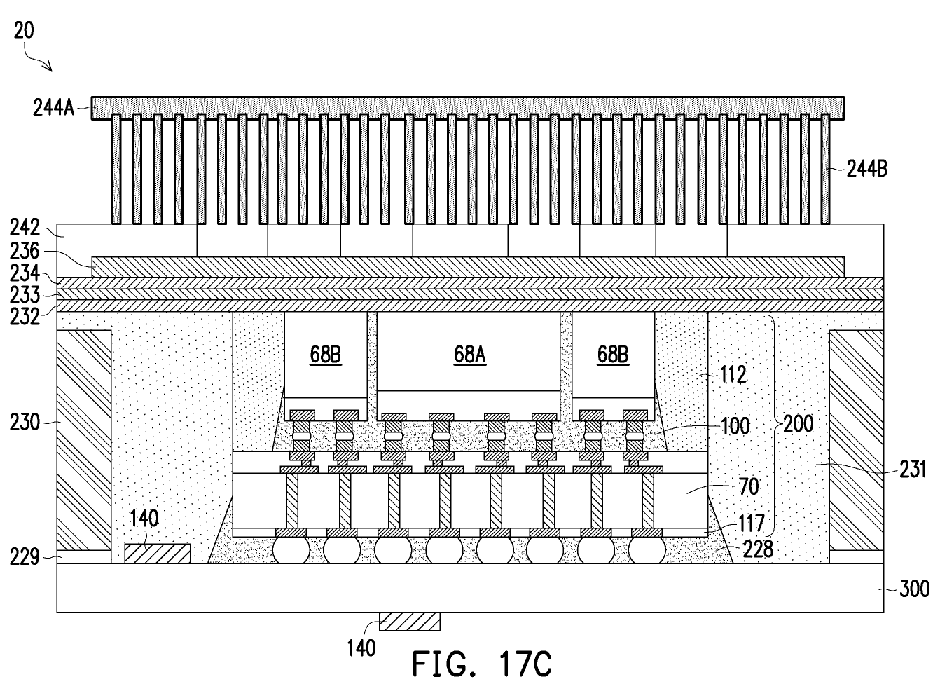

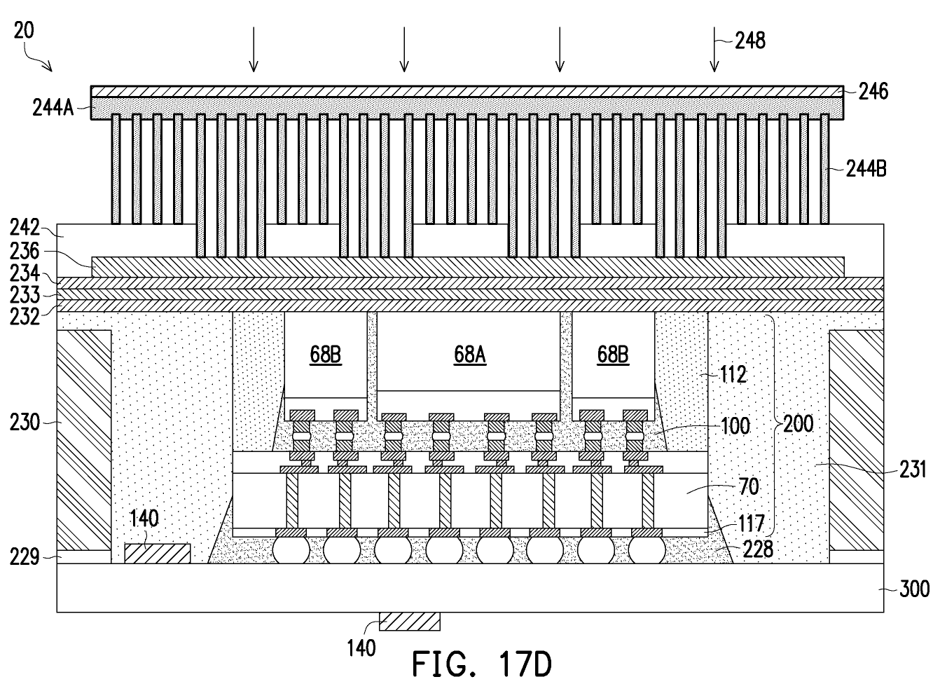

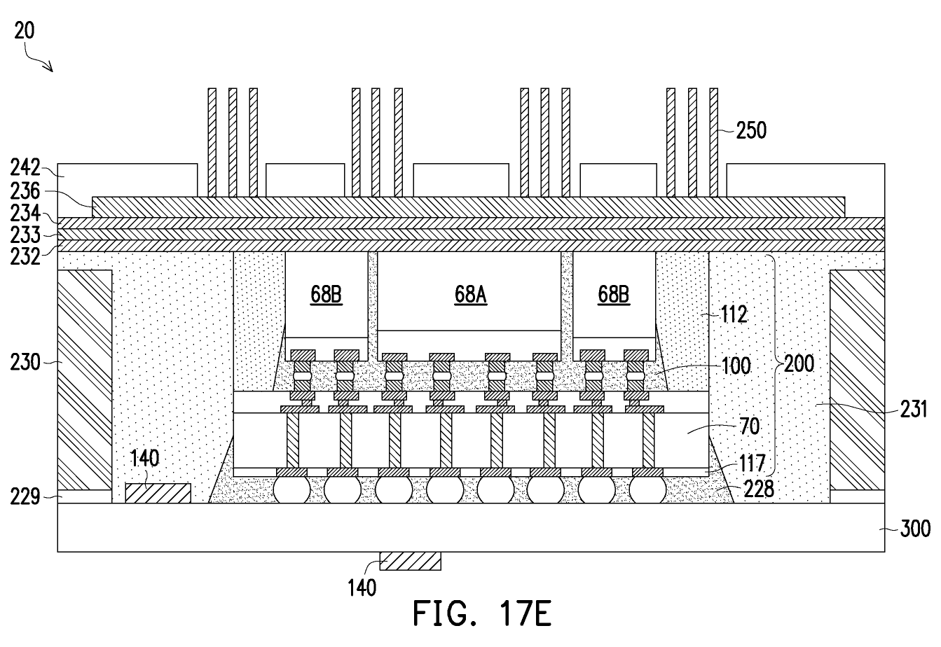

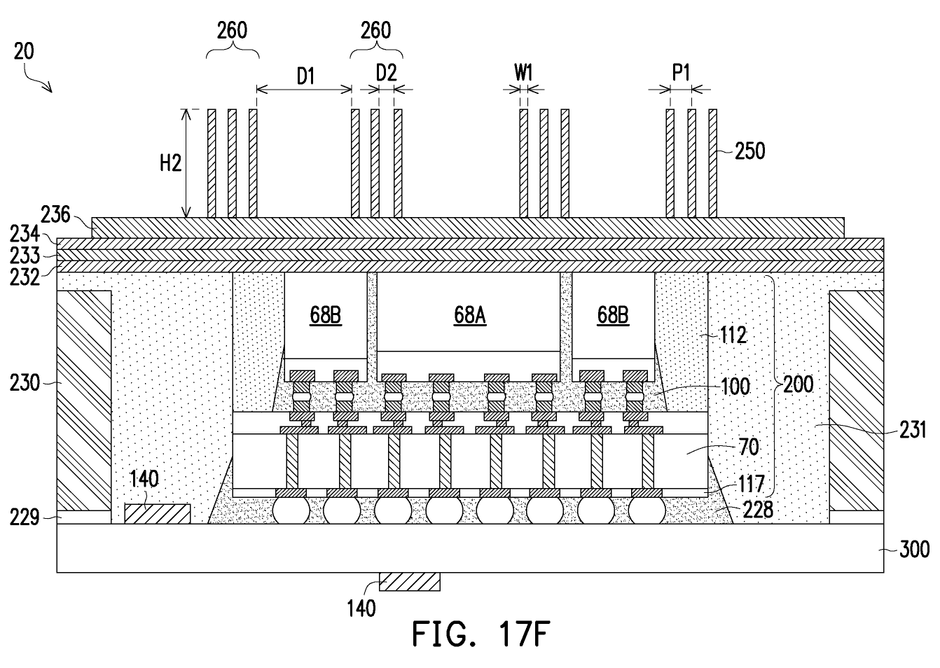

FIGS. 17A through 17F illustrate cross-sectional views of intermediate stages in the manufacturing of a package structure 20 in accordance with some other embodiments. Unless specified otherwise, like reference numerals in this embodiment (and subsequently discussed embodiments) represent like components in the embodiment shown in FIGS. 1 through 16B formed by like processes. Accordingly, the process steps and applicable materials may not be repeated herein. The initial steps of this embodiment are the same as shown in FIGS. 1 through 15. The package structure 20 of this embodiment allows for the use of two-phase immersion cooling in order to dissipate heat from the package structure 20.

In FIG. 17A, a photoresist 242 is formed over the thermal-conductive layer 235 and the thermal-conductive layer 236, and the photoresist 242 is patterned using photolithography techniques to form openings that expose portions of the thermal-conductive layer 236.

In FIG. 17B, top surfaces of the thermal-conductive layer 236 are exposed to a plasma 243 that is derived from O₂gas to remove any oxidation that may be present on the top surfaces of the thermal-conductive layer 236.

In FIG. 17C, a template 244 is placed on the top of the structure shown in FIG. 17B, such as on top surfaces of the photoresist 242 and over the top surfaces of the thermal-conductive layer 236. The template 244 may comprise any suitable sponge or sponge template compound having desired mechanical properties (for example, a desired structural integrity and Young’s modulus) such that it can be used in the formation of a plurality of nanowires 250 (shown subsequently in FIG. 17E). The template 244 may comprise a plurality of protrusions 244B on a base portion 244A, wherein each of the plurality of protrusions 244B is spaced apart from an adjacent one of the plurality of protrusions 244B. The template 244 is placed such that the plurality of protrusions 244B are disposed between the base portion 244A and the thermal-conductive layer 236. As will be described subsequently in FIG. 17E, each of the plurality of nanowires 250 is formed in the spaces between adjacent ones of the plurality of protrusions 244B.

In FIG. 17D, an electrode plate 246 is placed on a surface of the base portion 244A, and the entire structure is immersed in an electrolyte solution. The electrode plate 246 may comprise copper, or the like. Pressure 248 is applied to a top surface of the electrode plate 246 such that bottom surfaces of the plurality of protrusions 244B are pressed against the top surfaces of the thermal-conductive layer 236. In an embodiment, first portions of the plurality of protrusions 244B are in physical contact with the top surfaces of the thermal-conductive layer 236. Second portions of the plurality of protrusions 244B that overlap the photoresist 242 may be deformed as a result of the pressure 248.

In FIG. 17E, a plurality of nanowires 250 are then formed on the thermal-conductive layer 236 and in the spaces between adjacent ones of the first portions of the plurality of protrusions 244B using an electroplating process. During the electroplating process, a direct current is applied to the electrode plate 246 (see FIG. 17D) to dissolve atoms of the electrode plate 246 in the electrolyte solution, and the dissolved metal ions are used to form the plurality of nanowires 250. The nanowires 250 may be formed in a direction extending from the electrode plate 246 towards the thermal-conductive layer 236, wherein the nanowires 250 fill in spaces between the first portions of the plurality of protrusions 244B. The plurality of nanowires 250 may comprise copper, or the like. After the formation of the plurality of nanowires 250, the template 244 and the electrode plate 246 may be removed.

In FIG. 17F, the photoresist 242 is removed, such as through a suitable removal process such as tape peeling/separation. In an embodiment, the plurality of nanowires 250 maybe arranged in groupings 260, with a distance D1 between a first grouping 260 and an adjacent grouping 260 being in a range from 0.1 mm to 10 mm. In an embodiment, a distance D2 between adjacent ones of the plurality of nanowires 250 in a same grouping 260 is in a range from 5 nm to 300 nm. In an embodiment, a width W1 of each of the plurality of nanowires 250 may be in a range from 10 nm to 1500 nm. In an embodiment, a height H2 of the plurality of the nanowires 250 may be less than 0.5 mm. In an embodiment, a pitch P1 between a centerline of a first nanowire of the plurality of nanowires 250 and a centerline of an adjacent nanowire of the plurality of nanowires 250 may be greater than 10 nm and smaller than 300 nm. Although four groupings 260 of the plurality of nanowires 250 are illustrated in FIG. 17F, the number of groupings 260 of the plurality of nanowires 250 may be greater or smaller than four. Although each grouping 260 of the plurality of nanowires 250 is illustrated in FIG. 17F to show three nanowires, each grouping 260 may comprise any number of nanowires of the plurality of nanowires 250. In other embodiments (not shown in the Figures), the plurality of nanowires 250 may be disposed on the thermal-conductive layer 236 in a single grouping 260 that spans an entirety of the width of a top surface of the thermal-conductive layer 236. The formation of the plurality of nanowires 250 on the package structure 20 allows for the use of two-phase immersion cooling in order to dissipate heat from the package structure 20. This involves a process that includes directly immersing the package structure 20 in a dielectric liquid during operation.

Advantages may be achieved as a result of the formation of the package structure 20 comprising the package component 200 bonded to the substrate 300, and thereafter attaching the ring 230 to the substrate 300, wherein the ring surrounds the package component 200. The molding compound 231 is formed to fill spaces between the ring 230 and the package component 200. The thermal-conductive layers 235 and 236 are then formed over and in physical contact with the package component 200, and the plurality of nanowires 250 are formed on the thermal-conductive layer 236. These advantages include the removal of the need for multiple applications of thermal interface material, which results in reduced thermal resistance, better heat dissipation, and improved cooling performance, and are not limited thereto.

In accordance with an embodiment, a device includes a package substrate; an interposer having a first side bonded to the package substrate; a first die bonded to a second side of the interposer, the second side being opposite the first side; a ring on the package substrate, where the ring surrounds the first die and the interposer; a molding compound disposed between the ring and the first die, where the molding compound is in physical contact with the ring; and a plurality of thermal-conductive layers over and in physical contact with the molding compound and the first die, where the molding compound is disposed between the plurality of thermal-conductive layers and the ring. In an embodiment, the device further includes a cooling device over and coupled to the plurality of thermal-conductive layers with a thermal interface material. In an embodiment, the cooling device includes a liquid cooled cold-plate, a heat pipe cooling device, or a fan cooling device. In an embodiment, the device further includes a plurality of nanowires on the plurality of thermal-conductive layers. In an embodiment, the device further includes an underfill between the package substrate and the interposer, where the underfill is in physical contact with the molding compound. In an embodiment, the plurality of thermal-conductive layers includes a first thermal-conductive layer; a second thermal-conductive layer over the first thermal-conductive layer; a third thermal-conductive layer over the second thermal-conductive layer, where the first thermal-conductive layer, the second thermal-conductive layer, and the third thermal-conductive layer include different materials; and a copper layer over the third thermal-conductive layer. In an embodiment, the first thermal-conductive layer is aluminum, the second thermal-conductive layer is titanium, and the third thermal-conductive layer is nickel vanadium. In an embodiment, the first thermal-conductive layer is aluminum, the second thermal-conductive layer is titanium, and the third thermal- conductive layer is nickel copper.

In accordance with an embodiment, a device includes a package component including a first die; and an interposer; a substrate electrically connected to the first die, where the interposer is disposed between the first die and the substrate; a ring attached to the substrate; a molding compound surrounding the package component, where the molding compound is disposed between inner sidewalls of the ring and sidewalls of the package component; and a first thermal-conductive layer over the ring, the molding compound and the package component; and a heat dissipation structure over and coupled to the first thermal-conductive layer, where the heat dissipation structure is different from the first thermal-conductive layer. In an embodiment, the heat dissipation structure includes a liquid cooled cold-plate, a heat pipe cooling device, or a fan cooling device, and where the heat dissipation structure is coupled to the first thermal-conductive layer with a thermal interface material. In an embodiment, the first thermal-conductive layer includes copper. In an embodiment, the device further includes a plurality of thermal-conductive layers disposed between the first thermal-conductive layer and the package component, the plurality of thermal-conductive layers including a second thermal-conductive layer over and in physical contact with the package component and the molding compound; a third thermal-conductive layer over the second thermal-conductive layer; and a fourth thermal-conductive layer over the third thermal-conductive layer, where the fourth thermal-conductive layer and the first thermal-conductive layer are in physical contact. In an embodiment, the first thermal-conductive layer, the second thermal-conductive layer, the third thermal-conductive layer, and the fourth thermal-conductive layer include different materials. In an embodiment, sidewalls of the plurality of thermal-conductive layers are aligned with sidewalls of the first-thermal conductive layer.

In accordance with an embodiment, a method includes attaching a package component to a substrate; attaching a ring to the substrate, wherein the ring surrounds the package component; forming a molding compound over the ring, the package component, and the substrate, wherein the molding compound fills spaces between inner sidewalls of the ring and sidewalls of the package component; and depositing a plurality of thermal-conductive layers over the molding compound and the package component with a deposition process, the plurality of thermal-conductive layers in physical contact with the molding compound and the package component. In an embodiment, the method further includes planarizing the molding compound such that top surfaces of the molding compound and the package component are level, wherein depositing the plurality of thermal-conductive layers comprises depositing a first thermal-conductive layer, a second thermal-conductive layer and a third thermal-conductive layer sequentially over the molding compound, the package component and the substrate. In an embodiment, the method further includes depositing a fourth thermal-conductive layer over the third thermal-conductive layer; applying a thermal interface material to a top surface of the fourth thermal-conductive layer; and coupling a heat dissipation structure to the fourth thermal-conductive layer using the thermal interface material. In an embodiment, sidewalls of the first thermal-conductive layer, the second thermal-conductive layer, the third thermal-conductive layer, and the fourth thermal-conductive layer are aligned with each other. In an embodiment, the method further includes forming a seed layer over the third thermal-conductive layer; and plating a plurality of nanowires from the seed layer. In an embodiment, the first thermal-conductive layer, the second thermal-conductive layer, the third thermal-conductive layer, and the seed layer comprise different materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
attaching a package component to a substrate;
attaching a ring to the substrate, wherein the ring surrounds the package component;
forming a molding compound over the ring, the package component, and the substrate, wherein the molding compound fills spaces between inner sidewalls of the ring and sidewalls of the package component; and
depositing a plurality of thermal-conductive layers over the molding compound and the package component with a deposition process, the plurality of thermal-conductive layers in physical contact with the molding compound and the package component.

2. The method of claim 1, further comprising:
planarizing the molding compound such that top surfaces of the molding compound and the package component are level, wherein depositing the plurality of thermal-conductive layers comprises depositing a first thermal-conductive layer, a second thermal-conductive layer and a third thermal-conductive layer sequentially over the molding compound, the package component and the substrate.

3. The method of claim 2, further comprising:
depositing a fourth thermal-conductive layer over the third thermal-conductive layer;
applying a thermal interface material to a top surface of the fourth thermal-conductive layer; and
coupling a heat dissipation structure to the fourth thermal-conductive layer using the thermal interface material.

4. The method of claim 3, wherein sidewalls of the first thermal-conductive layer, the second thermal-conductive layer, and the third thermal-conductive layer are offset from a sidewall of the fourth thermal-conductive layer.

5. The method of claim 3, wherein the first thermal-conductive layer, the second thermal-conductive layer, and the third thermal-conductive layer comprise aluminum, titanium, nickel vanadium, gold, or copper.

6. The method of claim 5, wherein the first thermal-conductive layer, the second thermal-conductive layer, and the third thermal-conductive layer comprise different materials.

7. A method comprising:
forming a package component, wherein the package component comprises a first die and a second die;
attaching the package component to a substrate;
attaching a ring to the substrate, wherein the ring surrounds the package component;
filling spaces between inner sidewalls of the ring and sidewalls of the package component with a molding compound;
depositing a first thermal-conductive layer, a second thermal-conductive layer, and a third thermal-conductive layer sequentially over the molding compound and the package component, the first thermal-conductive layer being in physical contact with the molding compound and the package component; and
depositing a fourth thermal-conductive layer over the third thermal-conductive layer, wherein sidewalls of the first thermal-conductive layer, the second thermal-conductive layer, and the third thermal-conductive layer are offset from a sidewall of the fourth thermal-conductive layer.

8. The method of claim 7, wherein the first thermal-conductive layer, the second thermal-conductive layer, and the third thermal-conductive layer comprise aluminum, titanium, nickel vanadium, gold, or copper.

9. The method of claim 7, wherein the first thermal-conductive layer, the second thermal-conductive layer, and the third thermal-conductive layer comprise different materials.

10. The method of claim 9, wherein the first thermal-conductive layer comprises aluminum, the second thermal-conductive layer comprises titanium, and the third thermal-conductive layer comprises nickel vanadium.

11. The method of claim 7, wherein the fourth thermal-conductive layer comprises copper.

12. The method of claim 7, further comprising:
applying a thermal interface material to a top surface of the fourth thermal-conductive layer; and
coupling a heat dissipation structure to the fourth thermal-conductive layer through the thermal interface material.

13. The method of claim 12, wherein the heat dissipation structure comprises a liquid cooled cold-plate, a heat pipe cooling device, or a fan cooling device.

14. A method comprising:
attaching a package component and a ring to a substrate, wherein the ring surrounds the package component;
forming a molding compound over the substrate, wherein the molding compound surrounds the package component;
depositing a first thermal-conductive layer over the molding compound and the package component, the first thermal-conductive layer being in physical contact with the molding compound and the package component;
depositing a second thermal-conductive layer over the first thermal-conductive layer; and
depositing a third thermal-conductive layer over the second thermal-conductive layer, wherein the first thermal-conductive layer, the second thermal-conductive layer, and the third thermal-conductive layer comprise different materials.

15. The method of claim 14, wherein the first thermal-conductive layer comprises aluminum, the second thermal-conductive layer comprises titanium, and the third thermal-conductive layer comprises nickel vanadium.

16. The method of claim 14, wherein the first thermal-conductive layer, the second thermal-conductive layer, and the third thermal-conductive layer comprise aluminum, titanium, nickel vanadium, gold, or copper.

17. The method of claim 14, further comprising depositing a fourth thermal-conductive layer over the third thermal-conductive layer.

18. The method of claim 17, wherein the fourth thermal-conductive layer comprises copper.

19. The method of claim 17, wherein sidewalls of the first thermal-conductive layer, the second thermal-conductive layer, and the third thermal-conductive layer are offset from a sidewall of the fourth thermal-conductive layer.

20. The method of claim 17, further comprising:
applying a thermal interface material to a top surface of the fourth thermal-conductive layer; and
coupling a heat dissipation structure to the fourth thermal-conductive layer through the thermal interface material.
